(19) United States
(12) Patent Application Publication
(10) Pub. No.: US 2009/0191471 A1
(43) Pub. Date: Jul. 30, 2009

(54) Composition for cleaning a phase shift mask and associated methods

(76) Inventors: Dong-Hun Lee, Bucheon-si (KR); Hae-Young Jeong, Suwon-si (KR); Sung-Jae Han, Seongnam-si (KR); Han-Shin Lee, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 12/318,510

(22) Filed: Dec. 30, 2008

(30) Foreign Application Priority Data
Dec. 31, 2007 (KR) 2007-141297

(51) Int. Cl. G03F 1/00; C11D 7/18

(52) U.S. Cl. 430/5; 510/170

(57) ABSTRACT

A composition for cleaning a phase shift mask, including an organic acid ammonium salt, wherein a base ionization constant (K_{b}) of organic acid ions is larger than an acid ionization constant (Kₐ) of ammonium ions, hydrogen peroxide, and water, and associated methods.

### BACKGROUND

1. Field

Embodiments relate to a composition for cleaning a phase shift mask and associated methods.

2. Description of the Related Art

A phase shift mask (PSM) may be used during the manufacturing of semiconductor devices in order to utilize short wavelength light without reducing the depth of focus of an exposure process. The PSM has a phase shift layer formed by partially removing an upper portion of a transparent substrate such as a quartz substrate where a chrome layer has been coated to a predetermined depth. After light passes through the PSM, the light has a different optical path. For example, phase difference between a first light passing through a first opening of the PSM and a second light passing through a second opening next to the first opening may be about 180°. When lights having a phase difference of about 180° are added to each other, intensity becomes zero in a new wave pattern.

A cleaning process for removing minute contaminants remaining on a surface of the PSM may be performed thereto before the PSM is used.

In a conventional cleaning process for a chrome-coated mask, a composition including sulfinuric acid (H₂SO₄) may be used to remove a photoresist pattern, polymer generated by an etching process, and adhesives. Then, deionized water having a high temperature may be used for rinsing. However, the sulfate ions (SO₄²⁻) may not be completely removed from the chrome-coated mask, because sulfuric acid (H₂SO₄) has a relatively high viscosity.

FIG. 1 illustrates a scanning electron microscope (SEM) photo showing haze on a surface of a PSM after cleaning the PSM through a conventional cleaning process.

As shown in FIG. 1, sulfate (SO₄²⁻) ions partially remain on the PSM to form an opaque material on the PSM. A subsequent cleaning process may be performed to remove sulfate ions using a standard clean-1 (SC1) solution, which may cause haze in the PSM. The SC1 solution for removing minute contaminants may be prepared by mixing ammonium hydroxide (NH₄OH), hydrogen peroxide (H₂O₂), and water. In the subsequent cleaning process using the SC1 solution, ammonium ions (NH₄⁺) from the ammonium hydroxide may react with sulfate ions (SO₄²⁻) to precipitate ammonium sulfate (NH₄)₂SO₄. The ammonium sulfate may be removed by rinsing the PSM.

However, when the cleaning process using the SC1 solution is used to clean the PSM, hydroxide ions (OH⁻) from the ammonium hydroxide in the SC1 solution may cause damage to the phase shift layer. Accordingly, defects may be generated in the PSM. These defects may prevent the desired phase shift and transmittance of the PSM from being obtained.

A conventional cleaning solution including diluted ammonium hydroxide (NH₄OH), e.g., about 500 ppm, has been developed to clean a PSM. However, since the cleaning solution has a relatively low concentration of ammonium hydroxide (NH₄OH), sulfate ions (SO₄²⁻) may not be easily removed from the PSM, and thereby generate a haze and deteriorate the effectiveness of the PSM.

### SUMMARY

Embodiments are therefore directed to a composition for cleaning a phase shift mask and associated methods, which substantially overcome one or more of the problems due to the limitations and disadvantages of the prior art.

It is therefore a feature of an embodiment to provide a composition for cleaning a phase shift mask that removes sulfate ions after production of the phase shift mask, and prevents haze.

It is therefore another feature of an embodiment to provide a composition for cleaning a phase shift mask that does not damage the phase shift mask with hydroxide ions.

At least one of the above and other features and advantages may be realized by providing a composition for cleaning a phase shift mask, including an organic acid ammonium salt, wherein a base ionization constant (K_{b}) of organic acid ions is larger than an acid ionization constant (Kₐ) of ammonium ions, hydrogen peroxide, and water.

The base ionization constant (K_{b}) of the organic acid ions may be about 6.3×10⁻¹⁰ to about 3.0×10⁻⁴, and the acid ionization constant (Kₐ) of the ammonium ions may be about 5.0×10⁻¹⁰ to about 6.0×10⁻¹⁰.

A weight ratio of the organic acid ammonium salt and the hydrogen peroxide may be about 1:3 to about 1:5.

The composition for cleaning the phase shift mask may include about 2 to about 6 percent by weight of the organic acid ammonium salt, about 14 to about 18 percent by weight of the hydrogen peroxide, and about 78 to about 82 percent by weight of the water.

The organic acid ammonium salt may include at least one of ammonium acetate (NH₄CH₃COO), ammonium bicarbonate (NH₄HCO₃), ammonium carbonate ((NH₄)₂CO₃), and ammonium oxalate ((NH₄)₂C₂O₄).

At least one of the above and other features and advantages may also be realized by providing a method of cleaning a phase shift mask, including removing a photoresist and an etching residue from a substrate on which the phase shift mask is formed by performing a first cleaning process using a first solution including a sulfuric acid solution and removing remaining sulfate ions from the phase shift mask, without damaging the phase shift mask by performing a second cleaning process using a composition for cleaning the phase shift mask, the composition for cleaning the phase shift mask including hydrogen peroxide (H₂O₂), water, and an organic acid ammonium salt, wherein a base ionization constant (K_{b}) of organic acid ions is larger than an acid ionization constant (Kₐ) of ammonium ions.

The base ionization constant (K_{b}) of the organic acid ions may be about 6.3×10⁻¹⁰ to about 3.0×10⁻⁴, and the acid ionization constant (Kₐ) of the ammonium ions may be about 5.0×10⁻¹⁰ to about 6.0×10⁻¹⁰.

A weight ratio of the organic acid ammonium salt and the hydrogen peroxide may be about 1:3 to about 1:5.

The composition for cleaning the phase shift mask may include about 2 to about 6 percent by weight of the organic acid ammonium salt, about 14 to about 18 percent by weight of the hydrogen peroxide, and about 78 to about 82 percent by weight of the water.

The organic acid ammonium salt may include at least one of ammonium acetate (NH₄CH₃COO), ammonium bicarbonate (NH₄HCO₃), ammonium carbonate ((NH₄)₂CO₃), and ammonium oxalate ((NH₄)₂C₂O₄).

The composition for cleaning the phase shift mask may be provided on the substrate at a temperature of about 10° C. to about 45° C.

At least one of the above and other features and advantages may also be realized by providing a method of manufacturing a phase shift mask, including forming a phase shift layer and a light blocking layer on a transparent substrate, partially etching the phase shift layer and the light blocking layer to form a phase shift layer pattern and a preliminary light blocking layer exposing a phase region of about 0° of the substrate, forming a photoresist pattern on the phase shift layer pattern and the preliminary light blocking layer pattern, the photoresist pattern exposing a phase shift region of about 180° of the phase shift layer pattern, forming a light blocking layer pattern on the phase shift layer pattern by partially etching the preliminary light blocking layer pattern using the photoresist pattern as an etching mask, removing the photoresist pattern and an etching residue using a first solution including a sulfuric acid solution, and removing remaining sulfate ions without damaging the phase shift mask using a composition for cleaning the phase shift mask, the composition including an organic acid ammonium salt wherein a base ionization constant (K_{b}) of organic acid ions is larger than an acid ionization constant (Kₐ) of ammonium ions, hydrogen peroxide, and water.

The base ionization constant (K_{b}) of the organic acid ions may be about 6.3×10⁻¹⁰ to about 3.0×10⁻⁴, and the acid ionization constant (Kₐ) of the ammonium ions may be about 5.0×10⁻¹⁰ to about 6.0×10⁻¹⁰.

A weight ratio of the organic acid ammonium salt and the hydrogen peroxide may be about 1:3 to about 1:5.

The organic acid ammonium salt may include at least one of ammonium acetate (NH₄CH₃COO), ammonium bicarbonate (NH₄HCO₃), ammonium carbonate ((NH₄)₂CO₃), and ammonium oxalate ((NH₄)₂C₂O₄).

The composition for cleaning the phase shift mask may include about 2 to about 6 percent by weight of the organic acid ammonium salt, about 14 to about 18 percent by weight of the hydrogen peroxide, and about 78 to about 82 percent by weight of the water.

The composition for cleaning the phase shift mask may be provided on the substrate at a temperature of about 10° C. to about 45° C.

### BRIEF DESCRIPTION OF THE DRAWINGS

The above and other features and advantages will become more apparent to those of ordinary skill in the art by describing in detail exemplary embodiments thereof with reference to the attached drawings, in which:

FIG. 1 illustrates a scanning electron microscope (SEM) photograph illustrating hazes of a surface of a phase shift mask after cleaning the phase shift mask through a conventional cleaning process;

FIG. 2 illustrates a cross-sectional view of a phase shift mask cleaned using a composition for cleaning a phase shift mask according to an embodiment;

FIG. 3 illustrates a flow chart of a method of cleaning a phase shift mask according to an embodiment;

FIGS. 4 to 6 illustrate cross-sectional views of a method of manufacturing a phase shift mask according to an embodiment; and

FIG. 7 illustrates Table 1, listing phase differences for samples prepared in Example 1 and Comparative Examples 1 and 2.

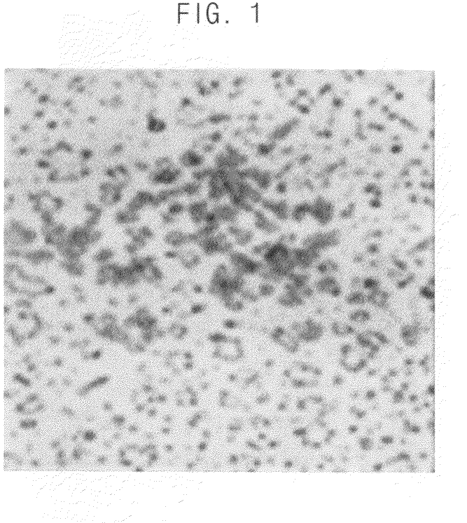

### DETAILED DESCRIPTION OF THE EMBODIMENTS

Korean Patent Application No. 2007-141297, filed on Dec. 31, 2008, in the Korean Intellectual Property Office, and entitled: “Composition for Cleaning a Phase Shift Mask, Method of Cleaning a Phase Shift Mask and Method of Manufacturing a Phase Shift Mask,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the expressions “at least one,” “one or more,” and “and/or” are open-ended expressions that are both conjunctive and disjunctive in operation. For example, each of the expressions “at least one of A, B, and C,” “at least one of A, B, or C,” “one or more of A, B, and C,” “one or more of A, B, or C” and “A, B, and/or C” includes the following meanings: A alone; B alone; C alone; both A and B together; both A and C together; both B and C together; and all three of A, B, and C together. Further, these expressions are open-ended, unless expressly designated to the contrary by their combination with the term “consisting of,” For example, the expression “at least one of A, B, and C” may also include an n^{th} member, where n is greater than 3, whereas the expression “at least one selected from the group consisting of A, B, and C” does not.

As used herein, the expression “or” is not an “exclusive or” unless it is used in conjunction with the term “either.” For example, the expression “A, B, or C” includes A alone; B alone; C alone; both A and B together; both A and C together; both B and C together; and all three of A, B, and C together, whereas the expression “either A, B, or C” means one of A alone, B alone, and C alone, and does not mean any of both A and B together; both A and C together; both B and C together; and all three of A, B, and C together.

As used herein, the terms “a” and “an” are open terms that may be used in conjunction with singular items or with plural items. For example, the term “an organic acid ammonium salt” may represent a single compound, e.g., ammonium acetate, or multiple compounds in combination, e.g., ammonium acetate mixed with ammonium oxalate.

Like or similar reference numerals refer to like or similar elements throughout. As used herein, the term “and/or” includes any and all combinations of one or more of the associated listed items.

It will be understood that, although the terms first, second, third etc. may be used herein to describe various elements, components, regions, layers, patterns, and/or sections, these elements, components, regions, layers, patterns, and/or sections should not be limited by these terms. These terms are only used to distinguish one element, component, region, layer, pattern, or section from another region, layer, pattern, or section. Thus, a first element, component, region, layer, or section discussed below could be termed a second element, component, region, layer, or section without departing from the teachings of example embodiments.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of illustratively idealized example embodiments (and intermediate structures) of embodiments. As such, variations from the shapes of the illustrations as a result, e.g., of manufacturing techniques and/or tolerances, are to be expected. Thus, example embodiments should not be construed as limited to the particular shapes of regions illustrated herein but are to include deviations in shapes that result, e.g., from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Composition for Cleaning a Phase Shift Mask

A composition for cleaning a phase shift mask may include an organic acid ammonium salt, hydrogen peroxide (H₂O₂), and water. The composition for cleaning the phase shift mask may be used in a cleaning process for the phase shift mask during semiconductor manufacturing processes.

In an embodiment, the phase shift mask cleaned using the composition for cleaning the phase shift mask may include a phase shift layer pattern defining a phase region of about 0°, and a light blocking layer pattern formed on the phase shift layer pattern to define a phase shift region of about 180°. The phase shift layer pattern may include a metal compound. For example, the phase shift layer pattern may include a silicon oxynitride, e.g., molybdenum silicon oxynitride (MoSiₓO_{y}N_{z}). Further, the light blocking layer pattern may include a metal compound, e.g., a metal oxide such as chromium oxide (CrOₓ).

In manufacturing the phase shift mask, including the phase shift layer pattern and the light blocking layer pattern, etching residues, e.g., metal silicon oxide and metal oxide, may remain on the phase shift mask. A photoresist used in forming the phase shift layer pattern and the light blocking layer pattern may also remain on the phase shift mask. The composition for cleaning the phase shift mask may completely remove the etching residues and the remaining photoresist from the phase shift mask.

In an embodiment, the composition for cleaning the phase shift mask may be used after removing a photoresist using a cleaning solution that includes a sulfuric acid (H₂SO₄) solution. Thus, remaining sulfate ions (SO₄²⁻) may be effectively removed from the phase shift mask. The sulfate ions (SO₄²⁻) from the cleaning solution including the sulfuric acid solution and ammonium ions (NH₄⁺) from the organic acid ammonium salt of the composition of an embodiment may react to precipitate ammonium sulfate. This salt may be easily removed from the phase shift mask.

The organic acid ammonium salt in the composition for cleaning the phase shift mask may include one or more of ammonium acetate (NH₄CH₃COO), ammonium bicarbonate (NH₄HCO₃), ammonium carbonate ((NH₄)₂CO₃), and ammonium oxalate ((NH₄)₂C₂O₄). Ammonium acetate (NH₄CH₃COO) is a soluble salt that forms acetate ions (CH₃COO⁻) corresponding to weak acid, and ammonium ions (NH₄⁺) corresponding to weak base. These weak acid ions and weak base ions may simultaneously hydrolyze according to following Reaction Schemes 1 and 2:

NH₄⁺+H₂O→NH₃+H₃O⁺ (Kₐ=5.7×10⁻¹⁰) [Reaction Scheme 1]

CH₃COO⁻+H₂O→CH₃COOH+OH⁻ (K_{b}=7.1×10⁻¹⁰) [Reaction Scheme 2]

In the organic acid ammonium salt in the composition of an embodiment, the base ionization constant (K_{b}) of the organic acid ions may be substantially larger than the acid ionization constant (Kₐ) of the ammonium ions in the above Reaction Schemes 1 and 2. Kₐ is a reaction constant for the formation of hydronium ions (H₃O⁺), whereas K_{b} is a reaction constant for the formation of hydroxide ions (OH⁻). The base ionization constant (K_{b}) of the organic acid ions may be about 6.0×10⁻¹⁰ to about 3.0×10⁻⁴. The acid ionization constant (Kₐ) of the ammonium ions may be about 5.0×10⁻¹⁰ to about 6.0×10⁻¹⁰. When ammonium acetate (NH₄CH₃COO) is used as the organic ammonium salt, Kₐ may be about 5.6×10⁻¹⁰, and K_{b} may be about 7.1×10⁻¹⁰. Thus, K_{b} may be substantially larger than Kₐ. Further, Kₐ and K_{b} of ammonium bicarbonate (NH₄HCO₃) may be about 5.6×10⁻¹⁰ and about 2.2×10⁻⁸, respectively. Kₐ and K_{b} of ammonium carbonate ((NH₄)₂CO₃) may be about 5.6×10⁻¹⁰ and about 2.1×10⁻⁴, respectively. Kₐ and K_{b} of ammonium oxalate ((NH₄)₂C₂O₄) may be about 5.6×10⁻¹⁰ and about 6.7×10⁻¹⁰, respectively. That is, K_{b} may be substantially larger than Kₐ when ammonium bicarbonate (NH₄HCO₃), ammonium carbonate ((NH₄)₂CO₃), and ammonium oxalate ((NH₄)₂C₂O₄) are used as the organic ammonium salt in the composition for cleaning the phase shift mask.

Because K_{b} may be larger than Kₐ, more hydroxide ions (OH⁻) may be generated than hdyronium ions (H₃O⁺). Hence, the hydroxide ions (OH⁻) generated by the hydrolysis may provide slightly basic conditions to which hydrogen peroxide (H₂O₂) may be added. Additionally, the change of transmittance and the phase shift of the phase shift mask may be considerably reduced because only a minute quantity of the hydroxide ions (OH⁻) may be formed using the composition of an embodiment.

The hydroxide ions (OH⁻) generated by the hydrolysis may be present at a concentration that does not damage the phase shift mask. The hydroxide ions (OH⁻) may react with hydrogen ions (H⁺), generated by the decomposition of ammonia (NH₃) and ammonium ions (NH₄⁺), and be neutralized, accelerating the decomposition of the ammonia (NH₃). As a result, the ammonium ions (NH₄⁺), which may cause a haze in the phase shift mask, may be reduced and ammonium sulfate (NH₄)₂SO₄ may be ionized to increase the solubility thereof. Reaction Schemes 3 and 4 illustrate the reduction of ammonium ions (NH₄⁺) and the ionization of ammonium sulfate (NH₄)₂SO₄.

NH₄⁺ [symbol] NH₃+H⁺ [Reaction Scheme 3]

(NH₄)₂SO₄ [symbol] 2NH₄⁺+SO₄²⁻ [Reaction Scheme 4]

In an embodiment, the composition for cleaning the phase shift mask may be obtained by mixing organic acid ammonium salt, hydrogen peroxide (H₂O₂), and water, at a weight ratio of about 1:4:20. The composition for cleaning the phase shift mask may be prepared by mixing about 2 to about 6 percent by weight of organic acid ammonium salt, about 14 to about 18 percent by weight of hydrogen peroxide, and about 78 to about 82 percent by weight of water. The water in the composition for cleaning the phase shift mask may include deionized water. Further, the ionization constant (K_{b}) of the weak acid may be larger than the ionization constant (Kₐ) of the weak base in the composition for cleaning the phase shift mask, so that the hydrolysis of positive ions and negative ions may occur to generate hydroxide ions and provide basic conditions for hydrogen peroxide. Therefore, the changes of transmittance and the phase shift of the phase shift mask caused by haze and/or defects may be effectively prevented because sulfate ions (SO₄²⁻) remaining on the phase shift mask after initial patterning and cleaning may be removed.

Method of Cleaning a Phase Shift Mask

Hereinafter, a method of cleaning a phase shift mask using a composition for cleaning a phase shift mask according to an embodiment will be described in detail.

The method of cleaning the phase shift mask may include cleaning and removing a photoresist pattern from a phase shift mask having a phase shift layer pattern and a light blocking layer pattern sequentially stacked on a transparent substrate.

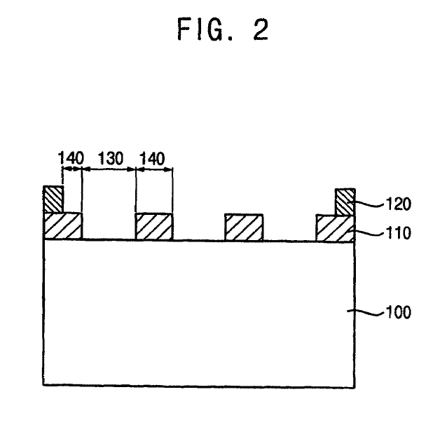

FIG. 2 illustrates a cross-sectional view of a method of cleaning a phase shift mask using a composition for cleaning a phase shift mask according to an embodiment.

Referring to FIG. 2, a phase shift mask may be formed on a transparent substrate 100. The phase shift mask may include a phase shift layer pattern 110 and a light blocking layer pattern 120, sequentially formed on the substrate 100. The substrate 100 may include quartz. A phase region of about 0° 130 of the substrate 100 may be defined by the phase shift layer pattern 110. A phase shift region of about 180° 140 of the phase shift layer pattern 110 may be defined by the light blocking layer pattern 120 that partially exposes the phase shift layer pattern 110.

In an embodiment, the light blocking layer pattern 120 may be formed by an etching process using a photoresist pattern (not illustrated) as an etching mask after forming the photoresist pattern exposing the phase shift region of about 180° 140 of the phase shift layer pattern 110.

After forming a phase shift layer (not illustrated) on the substrate 100, a light blocking layer (not illustrated) and a photoresist film (not illustrated) may be formed on the transparent substrate 100 through thin film deposition processes and a photolithography process including, e.g., an exposure process and a developing process. The photoresist film may define the phase region of about 0° 130 of the substrate 100. The substrate 100 may include a glass substrate containing quartz. The phase shift layer may include, e.g., molybdenum silicon oxynitride. The light blocking layer may include, e.g., chromium oxide.

In an embodiment, the light blocking layer and the phase shift layer may be sequentially patterned to form a preliminary light blocking layer pattern (not illustrated) and the phase shift layer pattern 110 on the substrate 100. The preliminary light blocking layer pattern may be positioned on a phase shift region of about 180° 140 of the phase shift layer pattern 110. The preliminary light blocking layer pattern may be partially removed to form the phase shift mask including the phase shift layer pattern 110 and the light blocking layer pattern 120.

A cleaning process for the phase shift mask may be performed on the substrate 100 having the phase shift mask to remove, e.g., the photoresist pattern from the light blocking layer pattern 120.

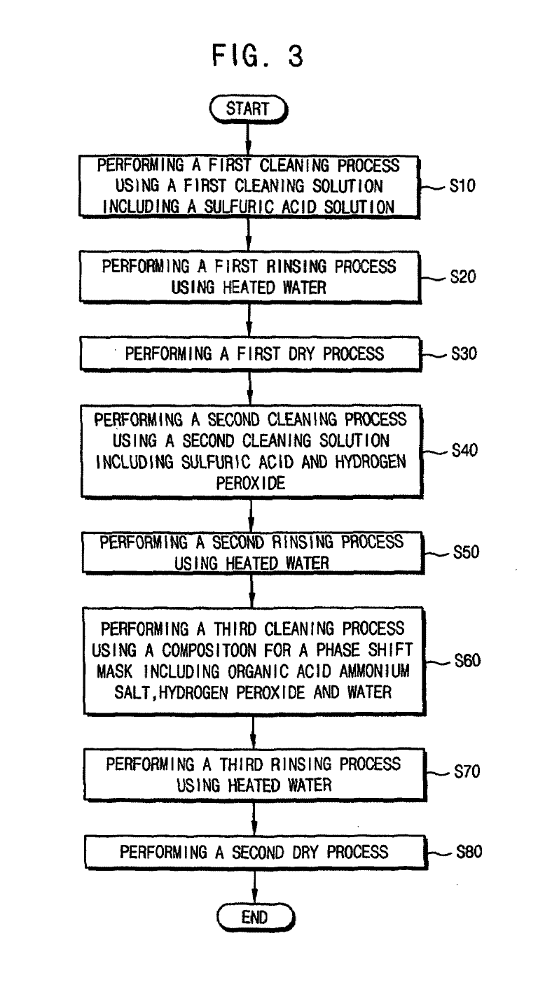

FIG. 3 illustrates a flow chart illustrating a method of cleaning a phase shift mask according to an embodiment.

Referring to FIG. 3, a first cleaning process may be performed on the phase shift mask using a first cleaning solution, including a sulfuric acid (H₂SO₄) solution, to remove photoresist and etching residues from the phase shift mask in step S10. An adhesive between the phase shift mask and a protection layer pattern (not illustrated) may also be removed in the first cleaning process.

The first cleaning process may be carried out using a batch-type cleaning apparatus or a single-type cleaning apparatus. When the photoresist pattern is removed using the batch-type cleaning apparatus, the phase shift mask may be immersed in the first cleaning solution for about 5 minutes to about 20 minutes. When the photoresist pattern is removed using the single-type cleaning apparatus, the phase shift mask may be contacted with the first cleaning solution for about 30 seconds to about 5 minutes. However, the contacting time of the photoresist and the first solution may be adjusted according to, e.g., an amount of remaining photoresist, characteristics of the layer patterns, etching residues generated in the etching process, etc.

In step S20, a first rinsing process may be performed on the phase shift mask using heated water after the first cleaning process. Deionized water, heated to a temperature of about 40° C. to about 100° C., may be used in the first rinsing process. After step S20, the sulfuric acid (H₂SO₄) solution used in the first cleaning process may remain on the phase shift mask because sulfuric acid has a relatively high viscosity.

In an embodiment, the first cleaning process and the first rinsing process may be repeated. That is, the first cleaning process and the first rinsing process may be performed on the phase shift mask more than twice.

A first drying process may be performed on the phase shift mask in step S30. The first drying process may be performed using a Marangoni drying system. With the Marangoni drying system, an isopropyl alcohol (IPA) vapor having a relatively low surface tension may be sprayed on the phase shift mask to remove any deionized water that may remain on the phase shift mask.

In step S40, a second cleaning process may be performed on the phase shift mask to remove organic contaminations, e.g., photoresist, remaining on the phase shift mask after the first cleaning process. The second cleaning process may be carried out using a second cleaning solution including a sulfuric acid (H₂SO₄) solution and a hydrogen peroxide (H₂O₂) solution. Hydrogen peroxide (H₂O₂) in the second cleaning solution may decompose into water (H₂O) and oxygen (O₂). Because hydrogen peroxide is a strong oxidizer, it may oxidize the photoresist remaining on the phase shift mask. Organic contaminants that may remain after the first cleaning process may be removed from the phase shift mask by oxidation.

A second rinsing process may be performed on the phase shift mask in step S50. The second rinsing process may be carried out using heated water having a temperature of about 40° C. to about 100° C. The heated water may include deionized water.

In an embodiment, an additional rinsing process using water at room temperature may be performed after the second rinsing process. Accordingly, the temperature of the heated phase shift mask may be reduced.

In step S60, a third cleaning process may be performed on the phase shift mask to remove residues that may remain after the first and second cleaning processes, e.g., sulfate ions (SO₄²⁻), without damaging the phase shift mask. The third cleaning process may be carried out using a composition for cleaning a phase shift mask including organic acid ammonium salt, hydrogen peroxide (H₂O₂), and water.

In an embodiment, the composition used in the third cleaning process may include an organic acid ammonium salt wherein the base ionization constant (K_{b}) is substantially larger than the acid ionization constant (Kₐ). The ionization constant (K_{b}) of the organic acid ions may be about 6.3×10⁻¹⁰ to about 3.0×10⁻⁴, and the ionization constant (Kₐ) of the ammonium ions may be about 5.0×10⁻¹⁰ to about 6.0×10⁻¹⁰. It may be possible to hydrolyze both positive ions and negative ions, to provide basic conditions for hydrogen peroxide (H₂O₂) without damaging the phase shift mask. The composition for cleaning the phase shift mask may be prepared by mixing organic acid ammonium salt with hydrogen peroxide (H₂O₂) at a weight ratio in a range of about 1:3 to about 1:5. For example, the composition for cleaning the phase shift mask in the third cleaning process may include about 2 to about 6 percent by weight of organic acid ammonium salt, about 14 to about 18 percent by weight of hydrogen peroxide (H₂O₂), and about 78 to about 82 percent by weight of water. The organic acid ammonium salt may include at least one of ammonium acetate (NH₄CH₃COO), ammonium bicarbonate (NH₄HCO₃), ammonium carbonate ((NH₄)₂CO₃), and ammonium oxalate ((NH₄)₂C₂O₄). The water in the composition for cleaning the phase shift mask may include deionized water.

In an embodiment, the composition for cleaning the phase shift mask may be provided to the phase shift mask at a temperature of about 10° C. to about 45° C. Maintaining the temperature at about 10° C. or greater may help ensure that removal of the photoresist occurs quickly. Maintaining the temperature at about 45° C. or less may help ensure that a phase shift layer pattern of the phase shift mask is not damaged while still sufficiently removing organic contaminants from the phase shift mask.

According to an embodiment, the third cleaning process may proceed using the composition for cleaning the phase shift mask including an organic acid ammonium salt without hydroxide, so that contaminants may be effectively removed from the phase shift mask without damaging the phase shift layer pattern of the phase shift mask. When sulfate ions (SO₄²⁻) remain on a phase shift mask, e.g., during a conventional cleaning process, light may be scattered on the phase shift mask in a photolithography process. This may result in haze in the phase shift mask, causing movement of a phase shift region of the phase shift layer pattern. However, since the cleaning process may be carried out using the composition for cleaning the phase shift mask including organic acid ammonium salt without hydroxide, ammonium ions (NH₄⁺) available to react with sulfate ions (SO₄²⁻) may have a relatively high concentration without concern for the damage caused by hydroxide. Accordingly, the generation of haze in the phase shift mask may be prevented, thereby improving the efficiency of the phase shift mask. As a result, changes of phase shift and transmittance of the phase shift mask caused by defects of the phase shift layer pattern may be avoided.

After the third cleaning process, a third rinsing process may be performed on the phase shift mask using heated water in step S70. The third rinsing process may be carried out at a temperature of about 40° C. to about 100° C., using heated deionized water.

A second drying process may be performed on the phase shift mask in a step S80. The second drying process may be performed using the Marangoni drying system, to remove the deionized water from the phase shift mask.

Method of Manufacturing a Phase Shift Mask

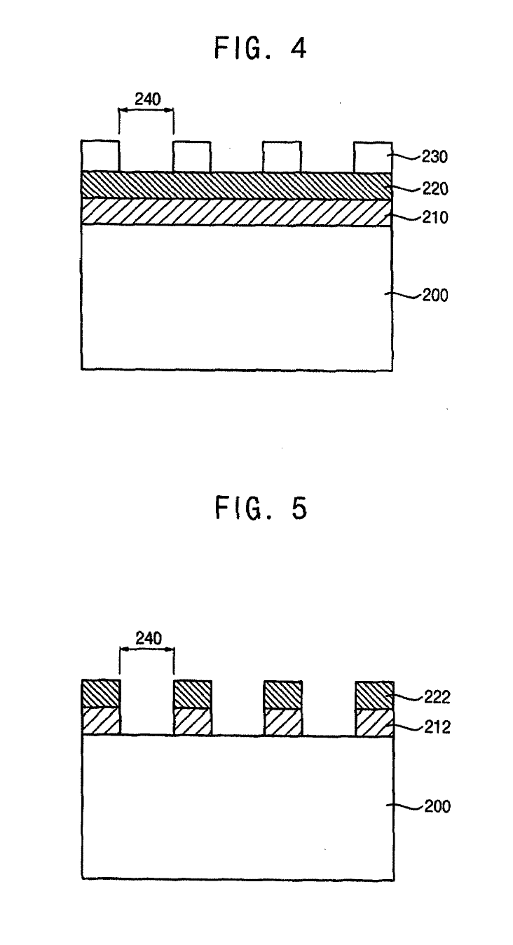

FIGS. 4 to 6 illustrate cross-sectional views of a method of manufacturing a phase shift mask in accordance with an embodiment.

Referring to FIG. 4, a phase shift layer 210 and a light blocking layer 220 may be formed on a transparent substrate 200. The transparent substrate 200 may include, e.g., a glass substrate of quartz.

The phase shift layer 210 may be formed on the substrate 100, e.g., using a metal and/or a metal compound. The phase shift layer 210 may include at least one of molybdenum (Mo), molybdenum silicide (MoSiₓ), molybdenum-silicon nitride (MoSiₓN_{y}), molybdenum-silicon oxy-nitride (MoSiₓO_{y}N_{z}), molybdenum-silicon-carbon nitride (MoSiₓC_{y}N_{z}), and molybdenum-silicon-carbon oxy-nitride (MoSiₓC_{y}O_{z}Nₖ). The phase shift layer 210 may be formed by, e.g., a sputtering process, a CVD process, an ALD process, a PLD process, an evaporation process, etc.

The light blocking layer 220 may also be formed on the phase shift layer 210 using, e.g., a metal and/or a metal compound by, e.g., a sputtering process, a CVD process, an ALD process, a PLD process, an evaporation process, etc. The light blocking layer 220 may include at least one of chromium (Cr), chromium nitride (CrNₓ), chromium carbide (CrCₓ), and/or chromium-carbon nitride (CrCₓN_{y}). In an embodiment, the phase shift layer 210 may be formed using molybdenum silicon oxynitride and the light blocking layer 220 may be formed using chromium.

After coating a first photoresist film (not illustrated) on the light blocking layer 220, a first photoresist pattern 230 for defining a phase region of about 0° 240 of the substrate 200 may be formed on the light blocking layer 220 by patterning the first photoresist film by an exposure process and a developing process.

Referring to FIG. 5, the phase region of about 0° 240 may be formed by partially etching the light blocking layer 220 and the phase shift layer 210 using the first photoresist pattern 230 as an etching mask. Thus, a preliminary light blocking layer pattern 222 and a phase shift layer pattern 212 may be obtained from the light blocking layer 220 and the phase shift layer 210 through the etching process. The preliminary light blocking layer pattern 222 and the phase shift layer pattern 212 may be formed by, e.g., a plasma dry etching process using an etching gas including fluorine (F), e.g., a carbon tetrafluoride (CF₄) gas, a sulfur tetrafluoride (SF₄) gas, a carbon monohydro-hexafluoride (CHF₆), etc. The etching gas may further include an oxygen (O₂) gas. A carrier gas, e.g., a helium gas and/or an argon gas, may be employed in the plasma dry etching process. Then, the first photoresist pattern 230 may be removed from the preliminary light blocking layer pattern 222. The first photoresist pattern 230 may be removed by, e.g., an ashing process and/or a strip process.

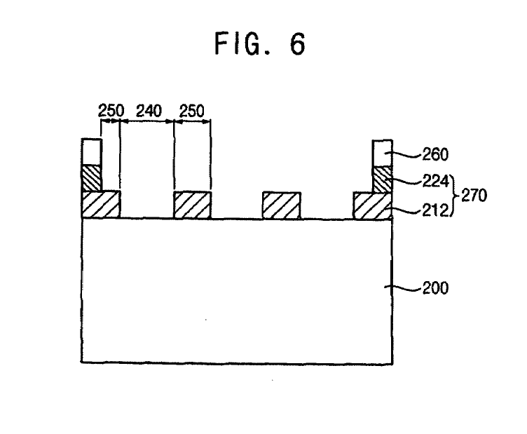

Referring to FIG. 6, a second photoresist film may be formed on the substrate 200 to cover the preliminary light blocking layer pattern 222. A second photoresist pattern 260, defining a phase shift region of about 180° 250 of the phase shift layer pattern 212, may be formed by patterning the second photoresist film by an exposure process and a developing process.

A light blocking layer pattern 224 may be formed on the phase shift layer pattern 212 by etching the preliminary light blocking layer pattern 222 of the phase shift region of about 180° 250 using the second photoresist pattern 260 as an etching mask. The light blocking layer pattern 224 may be formed by, e.g., a plasma dry etching process using an etching gas including fluorine, e.g., a carbon tetrafluoride gas, a sulfur tetrafluoride gas, a carbon monohydro-hexafluoride, etc. The etching gas may further include an oxygen gas. A carrier gas, e.g., a helium gas and/or an argon gas may be used in the plasma dry etching process. As a result, a phase shift mask 270 having the phase shift layer pattern 212 and the light blocking layer pattern 224 may be formed on the transparent substrate 200.

In an embodiment, a first light passing through the phase region of about 0° 240, exposed by the partial removal of the preliminary light blocking layer pattern 222, may have a phase different from a second light passing through the phase shift region of about 180° 250. Such phase difference between the first light and the second light may be about 180°. Thus, the phase shift mask 270 may be employed in forming minute patterns using a destructive interference between a light passing through the transparent substrate 200 and a light passing through a phase shift material in the phase shift mask 270 having a predetermined transmittance.

Referring to FIG. 6, a cleaning process may be performed on the substrate 200 having the phase shift mask 270. In the cleaning process, etching residues generated in the etching process for forming the phase shift mask 270 may be removed from the phase shift mask 270, and the second photoresist pattern 260 may be removed from the light blocking layer pattern 224. Further, photoresist remaining on the phase shift mask 270 may be removed from the light blocking layer 224 in the cleaning process.

In the cleaning process according to an embodiment, the substrate 200 having the phase shift mask 270 may be positioned on a loader of a strip apparatus. The cleaning process may then proceed according to an embodiment described above.

Hereinafter, a composition for cleaning a phase shift mask according to an Example and Comparative Examples will be described. However, the scope of the invention is not limited by the following Example and Comparative Examples.

### Example 1

4 percent by weight of ammonium carbonate ((NH₄)₂CO₃), 16 percent by weight of hydrogen peroxide (H₂O₂), and 80 percent by weight of deionized water were mixed to prepare a composition for cleaning a phase shift mask.

### Comparative Example 1

0.05 percent by weight of ammonium hydroxide (NH₄OH), 0.2 percent by weight of hydrogen peroxide (H₂O₂), and 99.75 percent by weight of deionized water were mixed to obtain a composition for cleaning a phase shift mask. The ionization constant (K_{b}) of the ammonium ion in ammonium hydroxide was 1.8×10⁻⁵.

### Comparative Example 2

4 percent by weight of ammonium nitrate (NH₄NO₃), 16 percent by weight of hydrogen peroxide, and 80 percent by weight of deionized water were mixed to prepare a composition for cleaning a phase shift mask.

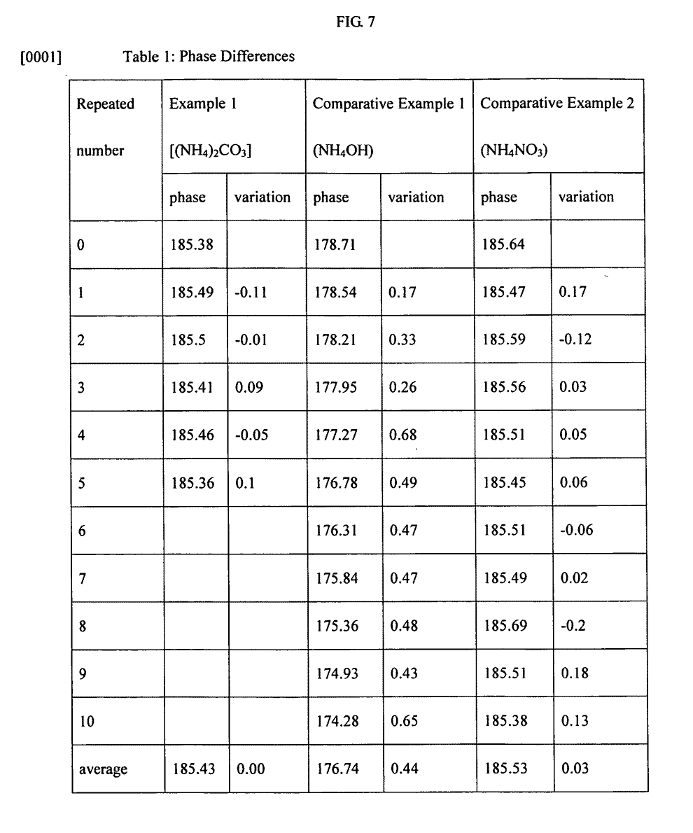

Measured changes of phase after cleaning a phase shift mask using compositions corresponding to Example 1 and Comparative Examples 1 and 2 are shown in Table 1 in FIG. 7. A first cleaning process was performed using a first cleaning solution including a sulfuric acid (H₂SO₄) solution, and a second cleaning process was performed using a second cleaning solution including a sulfuric acid solution and a hydrogen peroxide (H₂O₂) solution, on a plurality of phase shift masks. Then, the phase shift masks were each immersed in a different cleaning solution, including the compositions according to Example 1 and Comparative Examples 1 and 2, respectively, for about 5 minutes to remove organic residues and other minute residues from the phase shift masks. Phase values of a first light passing through the phase shift masks were measured using a phase measurement system, MPM-248, before the cleaning process. The cleaning processes using the compositions according to Example 1 and Comparative Example 1 and 2 were repeated ten times, and phase values of a second light passing through the phase shift masks were measured after each repetition of the cleaning process. Phase differences between the first light and the second light were determined. The phase differences were indicated by degree (°).

As shown in Table 1, after the cleaning process using the composition including ammonium carbonate ((NH₄)₂CO₃) according to Example 1, the phases of the second light passing through the phase shift mask were not substantially changed compared to the phases of the second light passing through the phase shift mask after the cleaning process using the composition including ammonium nitrate (NH₄NO₃) according to Comparative Example 2. After the cleaning process using the composition including ammonium nitrate (NH₄NO₃) according to Comparative Example 2, the phase change of the second light passing through the phase shift mask was about 0.03 degree. The ammonium nitrate was dissociated into ammonium ions (NH₄⁺) and nitrate ions (NO₃⁻) in deionized water. The nitrate ions (NO₃⁻), which may etch an oxide material, may be oxidized by hydrogen peroxide (H₂O₂). When light passes through the phase shift mask cleaned using the cleaning solution including organic acid ammonium without hydroxide ions (OH⁻), an appreciable phase change of the light was not observed.

When a conventional composition for cleaning a phase shift mask including diluted ammonium hydroxide (NH₄OH) is used in a cleaning process for a phase shift mask, a standard clean-1 (SC1) solution having diluted ammonium hydroxide (NH₄OH) of a relatively low concentration may be used to minimize damage to the phase shift mask generated by diluted hydroxide ions (OH⁻). For example, the standard clean-1 (SC1) solution including about 0.05 percent by weight ammonium hydroxide (NH₄OH) may be used to clean a phase shift mask. In this case, a phase change of about 0.4 degree was observed, and sulfate ions remaining on the phase shift mask may not be easily removed due to a low concentration of ammonium ions (NH₄⁺).

Meanwhile, in the cleaning process using the composition for cleaning a phase shift mask according to an embodiment, the phase change may be prevented because the phase shift mask is not damaged. Additionally, ammonium ions (NH₄⁺) may have a concentration sufficient to react with haze-causing sulfate ions.

According to an embodiment, a composition for cleaning a phase shift mask including organic acid ammonium salt without hydroxide ions (OH⁻), hydrogen peroxide (H₂O₂), and water may be used in cleaning processes performed on a phase shift mask, so that defects in the phase shift mask may be effectively prevented without damage to a phase shift layer of the phase shift mask. Thus, changes of phase shift and transmittance of the phase shift mask caused by such defects may be avoided. Further, the composition may have a high enough concentration of ammonium ions (NH₄⁺) to react with sulfate ions (SO₄²⁻), thereby preventing formation of haze.

The foregoing is illustrative of example embodiments, and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of example embodiments as defined in the claims. Therefore, it is to be understood that the foregoing is illustrative of example embodiments and is not to be construed as limited to the specific embodiments disclosed, and that modifications to the disclosed example embodiments, as well as other example embodiments, are intended to be included within the scope of the appended claims. The invention is defined by the following claims, with equivalents of the claims to be included therein.

What is claimed is:

1. A composition for cleaning a phase shift mask, comprising:
an organic acid ammonium salt, wherein a base ionization constant (K_{b}) of organic acid ions is larger than an acid ionization constant (Kₐ) of ammonium ions;
hydrogen peroxide; and
water.

2. The composition as claimed in claim 1, wherein the base ionization constant (K_{b}) of the organic acid ions is about 6.3×10⁻¹⁰ to about 3.0×10⁻⁴, and the acid ionization constant (Kₐ) of the ammonium ions is about 5.0×10⁻¹⁰ to about 6.0×10⁻¹⁰.

3. The composition as claimed in claim 1, wherein a weight ratio of the organic acid ammonium salt and the hydrogen peroxide is about 1:3 to about 1:5.

4. The composition as claimed in claim 1, wherein the composition for cleaning the phase shift mask includes:
about 2 to about 6 percent by weight of the organic acid ammonium salt,
about 14 to about 18 percent by weight of the hydrogen peroxide, and
about 78 to about 82 percent by weight of the water.

5. The composition as claimed in claim 1, wherein the organic acid ammonium salt includes at least one of ammonium acetate (NH₄CH₃COO), ammonium bicarbonate (NH₄HCO₃), ammonium carbonate ((NH₄)₂CO₃), and ammonium oxalate ((NH₄)₂C₂O₄).

6. A method of cleaning a phase shift mask, comprising:
removing a photoresist and an etching residue from a substrate on which the phase shift mask is formed by performing a first cleaning process using a first solution including a sulfuric acid solution; and
removing remaining sulfate ions from the phase shift mask, without damaging the phase shift mask by performing a second cleaning process using a composition for cleaning the phase shift mask, the composition for cleaning the phase shift mask including:
hydrogen peroxide (H₂O₂),
water, and
an organic acid ammonium salt, wherein a base ionization constant (K_{b}) of organic acid ions is larger than an acid ionization constant (Kₐ) of ammonium ions.

7. The composition as claimed in claim 1, wherein the base ionization constant (K_{b}) of the organic acid ions is about 6.3×10⁻¹⁰ to about 3.0×10⁻⁴, and the acid ionization constant (Kₐ) of the ammonium ions is about 5.0×10⁻¹⁰ to about 6.0×10⁻¹⁰.

8. The method as claimed in claim 6, wherein a weight ratio of the organic acid ammonium salt and the hydrogen peroxide is about 1:3 to about 1:5.

9. The method as claimed in claim 6, wherein the composition for cleaning the phase shift mask includes:
about 2 to about 6 percent by weight of the organic acid ammonium salt,
about 14 to about 18 percent by weight of the hydrogen peroxide, and
about 78 to about 82 percent by weight of the water.

10. The method as claimed in claim 6, wherein the organic acid ammonium salt includes at least one of ammonium acetate (NH₄CH₃COO), ammonium bicarbonate (NH₄HCO₃), ammonium carbonate ((NH₄)₂CO₃), and ammonium oxalate ((NH₄)₂C₂O₄).

11. The method as claimed in claim 6, wherein the composition for cleaning the phase shift mask is provided on the substrate at a temperature of about 10° C. to about 45° C.

12. A method of manufacturing a phase shift mask, comprising:
forming a phase shift layer and a light blocking layer on a transparent substrate;
partially etching the phase shift layer and the light blocking layer to form a phase shift layer pattern and a preliminary light blocking layer exposing a phase region of about 0° of the substrate;
forming a photoresist pattern on the phase shift layer pattern and the preliminary light blocking layer pattern, the photoresist pattern exposing a phase shift region of about 180° of the phase shift layer pattern;
forming a light blocking layer pattern on the phase shift layer pattern by partially etching the preliminary light blocking layer pattern using the photoresist pattern as an etching mask;
removing the photoresist pattern and an etching residue using a first solution including a sulfuric acid solution; and
removing remaining sulfate ions without damaging the phase shift mask using a composition for cleaning the phase shift mask, the composition including:
an organic acid ammonium salt wherein a base ionization constant (K_{b}) of organic acid ions is larger than an acid ionization constant (Kₐ) of ammonium ions,
hydrogen peroxide, and
water.

13. The composition as claimed in claim 1, wherein the base ionization constant (K_{b}) of the organic acid ions is about 6.3×10⁻¹⁰ to about 3.0×10⁻⁴, and the acid ionization constant (Kₐ) of the ammonium ions is about 5.0×10⁻¹⁰ to about 6.0×10⁻¹⁰.

14. The method as claimed in claim 12, wherein a weight ratio of the organic acid ammonium salt and the hydrogen peroxide is about 1:3 to about 1:5.

15. The method as claimed in claim 12, wherein the organic acid ammonium salt includes at least one of ammonium acetate (NH₄CH₃COO), ammonium bicarbonate (NH₄HCO₃), ammonium carbonate ((NH₄)₂CO₃), and ammonium oxalate ((NH₄)₂C₂O₄).

16. The method as claimed in claim 12, wherein the composition for cleaning the phase shift mask includes:
about 2 to about 6 percent by weight of the organic acid ammonium salt,
about 14 to about 18 percent by weight of the hydrogen peroxide, and
about 78 to about 82 percent by weight of the water.

17. The method as claimed in claim 12, wherein the composition for cleaning the phase shift mask is provided on the substrate at a temperature of about 10° C. to about 45° C.
